(19) United States
(12) Patent Application Publication
(10) Pub. No.: US 2020/0095683 A1
(43) Pub. Date: Mar. 26, 2020

(54) FILM FORMING METHOD AND FILM FORMING APPARATUS

(71) Applicant: TOKYO ELECTRON LIMITED, Tokyo (JP)

(72) Inventors: Takashi SAMESHIMA, Nirasaki City (JP); Koji MAEKAWA, Nirasaki City (JP); Katsumasa YAMAGUCHI, Nirasaki City (JP)

(21) Appl. No.: 16/570,397

(22) Filed: Sep. 13, 2019

(30) Foreign Application Priority Data
Sep. 20, 2018 (JP) 2018-176325

(51) Int. Cl. C23C 16/52; H01L 21/02; C23C 16/455; C23C 16/458; C23C 16/44

(52) U.S. Cl. CPC C23C 16/52; H01L 21/02521; H01L 21/0262; C23C 16/4412; C23C 16/45544; C23C 16/4586; C23C 16/45527

(57) ABSTRACT

There is provided a film forming method including: forming an initial tungsten film on a base film formed on a substrate by alternately supplying a B₂H₆ gas and a WF₆ gas while supplying a carrier gas into a processing container in a state in which the substrate is heated to a first temperature within the processing container maintained in a depressurized state; and forming a main tungsten film on the initial tungsten film by alternately supplying a tungsten-containing gas and a reducing gas for reducing the tungsten-containing gas into the processing container in a state in which the substrate is heated to a second temperature higher than the first temperature within the processing container maintained in the depressurized state.

### CROSS-REFERENCE TO RELATED APPLICATION

This application is based upon and claims the benefit of priority from Japanese Patent Application No. 2018-176325, filed on Sep. 20, 2018, the entire contents of which are incorporated herein by reference.

### TECHNICAL FIELD

The present disclosure relates to a film forming method and a film forming apparatus.

### BACKGROUND

There is known a method of forming a tungsten film on a base film through an ALD method using a tungsten chloride gas (see, for example, Patent Document 1). In this method, an initial tungsten film is formed prior to the formation of a main tungsten film. The main tungsten film is formed by sequentially supplying a tungsten chloride gas and a reducing gas while performing a purging step between the supply of the tungsten chloride gas and the supply of the reducing gas. The initial tungsten film is formed by sequentially supplying the tungsten chloride gas and the reducing gas in a state in which the supply amount of the tungsten chloride gas is set to be smaller than that in forming the main tungsten film, while performing the purging step in the course of the sequential supply. According to this method, it is possible to form a tungsten film having good adhesion on the base film.

### PRIOR ART DOCUMENT

### Patent Documents

Patent Document 1: Japanese Laid-Open Patent Publication No. 2016-186094

### SUMMARY

According to an embodiment of the present disclosure, there is provided a film forming method including: forming an initial tungsten film on a base film formed on a substrate by alternately supplying a B₂H₆ gas and a WF₆ gas while supplying a carrier gas into a processing container in a state in which the substrate is heated to a first temperature within the processing container maintained in a depressurized state; and forming a main tungsten film on the initial tungsten film by alternately supplying a tungsten-containing gas and a reducing gas for reducing the tungsten-containing gas into the processing container in a state in which the substrate is heated to a second temperature higher than the first temperature within the processing container maintained in the depressurized state.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to an embodiment.

FIG. 2 is a schematic view illustrating am exemplary configuration of a film forming apparatus suitable for carrying out a film forming method of an embodiment.

FIG. 3 is a view illustrating a gas supply sequence in the film forming method of an embodiment.

FIG. 4 is a view representing a relationship between a set temperature of a stage and a film forming rate.

FIG. 5 is a view representing a relationship between the number of cycles and a film thickness of a tungsten film.

FIG. 6 is a view representing a relationship between the type of carrier gas and a concentration of fluorine in a base film.

### DETAILED DESCRIPTION

Hereinafter, non-limitative exemplary embodiments of the present disclosure will now be described with reference to the accompanying drawings. In all the accompanying drawings, the same or corresponding members or components will be denoted by the same or corresponding reference numerals, and redundant explanations thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### (Film Forming Method)

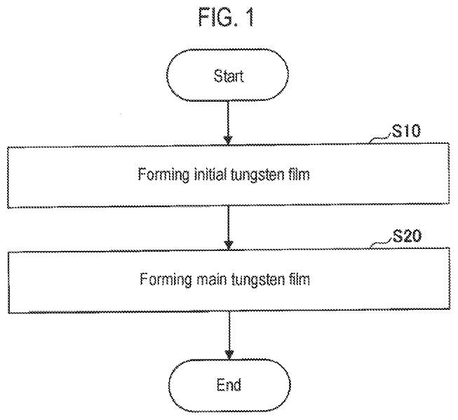

A film forming method according to an embodiment will be described. FIG. 1 is a flowchart illustrating the film forming method according to an embodiment.

As illustrated in FIG. 1, the film forming method of an embodiment includes a step of forming an initial tungsten film (S10) and a step of forming a main tungsten film (S20).

In the step of forming the initial tungsten film (S10), the initial tungsten film is formed on a base film formed on a front surface of a substrate through an atomic layer deposition (ALD) method. In an embodiment, first, the substrate having the base film formed thereon is accommodated in a processing container, the interior of the processing container is maintained in a depressurized state, and the substrate is heated to a first temperature. Subsequently, a carrier gas is supplied into the processing container. The initial tungsten film is formed on the base film by alternately supplying a diborane (B₂H₆) gas and a tungsten hexafluoride (WF₆) gas while performing a purging process in the course of the alternate supply. The first temperature is lower than a second temperature used in the step of forming the main tungsten film (S20) described later. The first temperature may be 200 degrees C. to 250 degrees C. This makes it possible to form the initial tungsten film at a slower film forming rate compared with the main tungsten film. Thus, it is possible to control a film thickness of the initial tungsten film with high accuracy even if the film thickness is reduced. From the viewpoint of forming the initial tungsten film in an ALD mode, and especially, adjusting the film forming rate with high accuracy, the first temperature may fall within a range of 200 to 220 degrees C. The base film may be a Ti-containing film such as a titanium nitride (TiN) film, a titanium silicon nitride (TiSiN) film or the like, or an Al-containing film such as an aluminum nitride (AlN) film or the like. The carrier gas may be a gas containing at least one of a hydrogen (H₂) gas, an argon (Ar) gas, and a nitrogen (N₂) gas. The purge gas may be an N₂ gas.

In addition, in the step of forming the initial tungsten film (S10), the carrier gas may be selected based on a relationship information representative of the relationship between the type of carrier gas and the film forming rate of the initial tungsten film. Thus, it is possible to adjust a concentration of fluorine in the base film, which is caused by the WF₆ gas used when forming the initial tungsten film. The relationship information may be a table, a mathematical expression or the like. As an example, by using a carrier gas containing an H₂ gas as a main component, it is possible to reduce the fluorine concentration in the base film. The reason why the fluorine concentration in the base film is adjustable will be described later.

The step of forming the initial tungsten film (S10) is performed in a state in which the supply amount of the WF₆ gas is set to be smaller than that in the step of forming the main tungsten film (S20). Therefore, an etched amount of the base film is small, and the initial tungsten film functions as a barrier for the WF₆ gas to the base film when forming the main tungsten film with a larger supply amount of the WF₆ gas. Thus, it is possible to effectively suppress the etching of the base film.

In the step of forming the main tungsten film (S20), the main tungsten film is formed on the initial tungsten film through an ALD method. In an embodiment, first, the substrate having an initial tungsten film formed on the front surface of the base film is accommodated in the processing container, the interior of the processing container is maintained in a depressurized state, and the substrate is heated to a second temperature higher than the first temperature. Subsequently, a tungsten-containing gas and a reducing gas for reducing the tungsten-containing gas are alternately supplied into the processing container while performing a purging process in the course of the alternate supply. Thus, the main tungsten film is formed on the initial tungsten film. The second temperature may be 300 degrees C. to 600 degrees C. The tungsten-containing gas may be a tungsten hexachloride gas such as a tungsten hexachloride (WCl₆) gas, a tungsten pentachloride (WCl₅) gas or the like, or a tungsten fluoride gas such as a tungsten hexafluoride (WF₆) gas. The tungsten-containing gas may be generated by sublimating a film forming raw material, which remains in a solid state at normal temperature.

Alternatively, the tungsten-containing gas may be generated by vaporizing a film forming raw material, which remains in a liquid state at normal temperature. The reducing gas may be any reducing gas containing hydrogen. As an example, the reducing gas may be a hydrogen (H₂) gas, a monosilane (SiH₄) gas, a B₂H₆ gas, an ammonia (NH₃) gas, a phosphine (PH₃) gas, or a dichlorosilane (SiH₂Cl₂) gas. In addition, the reducing gas may be a gas obtained by combining two or more kinds of gases selected from the H₂ gas, the SiH₄ gas, the B₂H₆ gas, the NH₃ gas, the PH₃ gas, and the SiH₂Cl₂ gas. However, from the viewpoint of further reducing impurities in the tungsten film to obtain a low resistance value, the H₂ gas may be used.

### (Film Forming Apparatus)

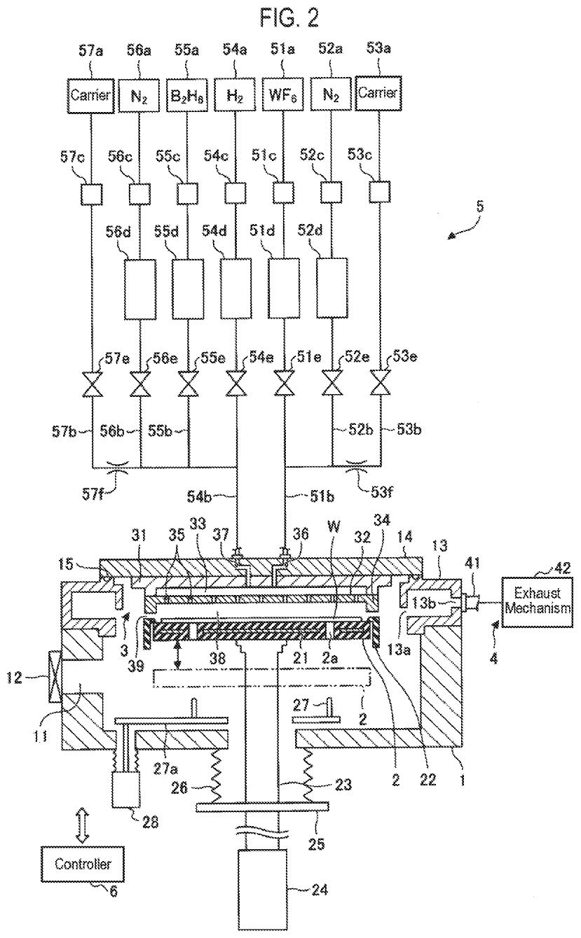

An example of a film forming apparatus, which implements the film forming method, will be described. FIG. 2 is a schematic view illustrating an exemplary configuration of the film forming apparatus suitable for carrying out the film forming method of the embodiment.

The film forming apparatus includes a processing container 1, a stage 2, a shower head 3, an exhaust part 4, a gas supply mechanism 5, and a controller 6.

The processing container 1 is made of a metal such as aluminum, and has a substantially cylindrical shape. The processing container 1 accommodates a semiconductor wafer (hereinafter referred to as “wafer W”) as a substrate. A loading/unloading port 11 through which the wafer W is transferred is formed on a side wall of the processing container 1. The loading/unloading port 11 is opened/closed by a gate valve 12. An annular exhaust duct 13 having a rectangular cross section is provided on a main body of the processing container 1. A slit 13a is formed in the exhaust duct 13 along an inner peripheral surface of the exhaust duct 13. An exhaust port 13b is formed on an outer wall of the exhaust duct 13. A ceiling wall 14 is provided on the exhaust duct 13 so as to close an upper opening of the processing container 1. The exhaust duct 13 and the ceiling wall 14 is hermetically sealed from each other with a seal ring 15.

The stage 2 horizontally supports the wafer W inside the processing container 1. The stage 2 is formed in a disk shape having a size corresponding to the wafer W, and is supported by a support member 23. The stage 2 is formed of a ceramic material such as aluminum nitride (AlN) or a metal material such as aluminum or nickel alloy. A heater 21 is embedded in the stage 2 in order to heat the wafer W. The heater 21 generates heat based on power provided from a heater power supply (not illustrated). A temperature of the wafer W is controlled to a predetermined temperature by controlling the output of the heater 21 based on a temperature signal obtained by a thermocouple (not illustrated) provided in the vicinity of the upper surface of the stage 2. The stage 2 is provided with a cover member 22 formed of ceramic such as alumina so as to cover an outer peripheral area of the upper surface of the stage 2 and a lateral surface thereof.

The support member 23 is provided in the bottom surface of the stage 2 to support the stage 2. The support member 23 extends downward of the processing container 1 through a hole formed in the bottom wall of the processing container 1 from the center of the bottom surface of the stage 2. A lower end of the support member 123 is connected to a lifting mechanism 24. The substrate stage 2 is moved upward and downward via the support member 23 by the lifting mechanism 24 between a processing position illustrated in FIG. 1 and a transfer position where the wafer W can be transferred. The transfer position is indicated by a dashed double-dotted line below the processing position. A flange 25 is mounted on the support member 23 below the processing container 1. A bellows 26 is provided between the bottom surface of the processing container 1 and the flange 25 to isolate an internal atmosphere of the processing container 1 from ambient air. The bellows 26 expands and contract along with the upward-downward movement of the stage 2.

Three wafer support pins 27 (only two are illustrated in FIG. 2) are provided in the vicinity of the bottom surface of the processing container 1 to protrude upward from a lifting plate 27a. The wafer support pins 27 are moved upward and downward via the lifting plate 27a by a lifting mechanism 28 provided below the processing container 1. The wafer support pins 27 are inserted into respective through-holes 2a provided in the stage 2 when the stage 2 is located at the transfer position, and are moved upward and downward on the upper surface of the stage 2. By moving upward and downward the wafer support pins 27, the wafer W is delivered between a wafer transfer mechanism (not illustrated) and the stage 2.

The shower head 3 supplies a processing gas into the processing container 1 in the form of a shower. The shower head 3 is made of metal, and is provided to face the stage 2. The shower head 3 has a diameter, which is substantially the same as that of the stage 2. The shower head 3 includes a main body 31 fixed to the ceiling wall 14 of the processing container 1 and a shower plate 32 connected to the lower side of the main body 31. A gas diffusion space 33 is formed between the main body 31 and the shower plate 32. Gas introduction holes 36 and 37, which penetrate through the ceiling wall 14 of the processing container 1 and the center of the main body 31, are connected to the gas diffusion space 33. A protruded portion 34 annularly protruding downward is formed on a peripheral edge of the shower plate 32. Gas ejection holes 35 are formed in a flat surface inward of the protruded portion 34. In the state in which the stage 2 is located at the processing position, a processing space 38 is formed between the stage 2 and the shower plate 32. An upper surface of the cover member 22 and the protruded portion 34 are close to each other so as to form an annular gap 39.

The exhaust part 4 exhausts the interior of the processing container 1. The exhaust part 4 includes an exhaust pipe 41 connected to the exhaust port 13b, and an exhaust mechanism 42 connected to the exhaust pipe 41. The exhaust mechanism 42 includes a vacuum pump, a pressure control valve and the like. During the processing, the gas in the processing container 1 reaches the exhaust duct 13 via the slit 13a, and is exhausted from the exhaust duct 13 through the exhaust pipe 41 by the exhaust mechanism 42.

The gas supply mechanism 5 supplies the processing gas into the processing container 1. The gas supply mechanism 6 includes a WF₆ gas source 51a, an N₂ gas source 52a, a carrier gas source 53a an H₂ gas source 54a, a B₂H₆ gas source 55a, an N₂ gas source 56a, and a carrier gas source 57a.

The WF₆ gas source 51a supplies a WF₆ gas into the processing container 1 through a gas supply line 51b. The gas supply line 51b is provided with a flow rate controller 51c, a storage tank 51d, and a valve 51e from the upstream side. A downstream side of the valve 51e in the gas supply line 51b is connected to the gas introduction hole 36. The WF₆ gas supplied from the WF₆ gas source 51a is temporarily stored in the storage tank 51d before being supplied into the processing container 1. The WF₆ gas is pressurized to have a predetermined pressure inside the storage tank 51d, and is then supplied into the processing container 1. The supply and cutoff of the WF₆ gas from the storage tank 51d into the processing container 1 are performed by the opening/closing of the valve 51e. By temporarily storing the WF₆ gas in the storage tank 51d as described above, it is possible to stably supply the WF₆ gas into the processing container 1 at a relatively large flow rate.

The N₂ gas source 52a supplies an N₂ gas as a purge gas, into the processing container 1 through a gas supply line 52b. The gas supply line 52b is provided with a flow rate controller 52c, a storage tank 52d, and a valve 52e from the upstream side. The downstream side of the valve 52e in the gas supply line 52b is connected to the gas supply line 51b. The N₂ gas supplied from the N₂ gas source 52a is temporarily stored in the storage tank 52d before being supplied into the processing container 1. The N₂ gas is pressurized to have a predetermined pressure inside the storage tank 52d, and is then supplied into the processing container 1. The supply and cutoff of the N₂ gas from the storage tank 52d into the processing container 1 are performed by the opening/closing of the valve 52e. By temporarily storing the N₂ gas inside the storage tank 52d as described above, it is possible to stably supply the N₂ gas into the processing container 1 at a relatively large flow rate.

The carrier gas source 53a supplies a carrier gas into the processing container 1 through a gas supply line 53b. The gas supply line 53b is provided with a flow rate controller 53c, a valve 53e, and an orifice 53f from the upstream side. The downstream side of the orifice 53f in the gas supply line 53b is connected to the gas supply line 51b. The carrier gas supplied from the carrier gas source 53a is continuously supplied into the processing container 1 during the film formation. The supply and cutoff of the carrier gas from the carrier gas source 53a into the processing container 1 are performed by the opening/closing of the valve 53e. Although the gases are supplied to the gas supply lines 51b and 52b at a relatively large flow rate by the storage tanks 51d and 52d, the gases supplied to the gas supply lines 51b and 52b are prevented from flowing backward to the gas supply line 53b by the orifice 53f. The carrier gas contains at least one of an H₂ gas, an Ar gas, and an N₂ gas.

The H₂ gas source 54a supplies an H₂ gas as a reducing gas into the processing container 1 through a gas supply line 54b. The gas supply line 54b is provided with a flow rate controller 54c, a storage tank 54d, and a valve 54e from the upstream side. The downstream side of the gas supply line 54b is connected to the gas introduction hole 37. The H₂ gas supplied from the H₂ gas source 54a is temporarily stored in the storage tank 54d before being supplied into the processing container 1. The H₂ gas is pressurized to have a predetermined pressure inside the storage tank 54d, and is then supplied into the processing container 1. The supply and cutoff of the H₂ gas from the storage tank 54d into the processing container 1 are performed by the opening/closing of the valve 54e. By temporarily storing the H₂ gas inside the storage tank 54d as described above, it is possible to stably supply the H₂ gas into the processing container 1 at a relatively large flow rate.

The B₂H₆ gas source 55a supplies a B₂H₆ gas as a reducing gas into the processing container 1 through a gas supply line 55b. The gas supply line 55b is provided with a flow rate controller 55c, a storage tank 55d, and a valve 55e from the upstream side. The downstream side of the valve 55e in the gas supply line 55b is connected to the gas supply line 54b. The B₂H₆ gas supplied from the B₂H₆ gas source 55a is temporarily stored inside the storage tank 55d before being supplied into the processing container 1. The B₂H₆ gas is pressurized to have a predetermined pressure inside the storage tank 55d, and is then supplied into the processing container 1. The supply and cutoff of the B₂H₆ gas from the storage tank 55d into the processing container 1 are performed by the opening/closing of the valve 55e. By temporarily storing the B₂H₆ gas inside the storage tank 55d as described above, it is possible to stably supply the B₂H₆ gas into the processing container 1 at a relatively large flow rate.

The N₂ gas source 56a supplies an N₂ gas as a purge gas into the processing container 1 through a gas supply line 56b. The gas supply line 56b is provided with a flow rate controller 56c, a storage tank 56d, and a valve 56e from the upstream side. The downstream side of the valve 56e in the gas supply line 56b is connected to the gas supply line 54b. The N₂ gas supplied from the N₂ gas source 56a is temporarily stored inside the storage tank 56d before being supplied into the processing container 1. The N₂ gas is pressurized to have a predetermined pressure inside the storage tank 56d, and is then supplied into the processing container 1. The supply and cutoff of the N₂ gas from the storage tank 56d into the processing container 1 are performed by the opening/closing of the valve 56e. By temporarily storing the N₂ gas inside the storage tank 56d as described above, it is possible to stably supply the N₂ gas into the processing container 1 at a relatively large flow rate.

The carrier gas source 57a supplies a carrier gas into the processing container 1 through a gas supply line 57b. The gas supply line 57b is provided with a flow rate controller 57c, a valve 57e, and an orifice 57f from the upstream side. The downstream side of the orifice 57f in the gas supply line 57b is connected to the gas supply line 54b. The carrier gas supplied from the carrier gas source 57a is continuously supplied into the processing container 1 during the film formation. The supply and cutoff of the carrier gas from the carrier gas source 57a into the processing container 1 are performed by the opening/closing of the valve 57e. Although the gases are supplied to the gas supply lines 54b, 55b, and 56b at a relatively large flow rate by the storage tanks 54d. 55d, and 56d, the gases supplied to the gas supply lines 54b, 55b, and 56b are prevented from flowing backward to the gas supply line 57b by the orifice 57f. The carrier gas contains at least one of an H₂ gas, an Ar gas, and an N₂ gas.

The controller 6 may be a computer, and includes a central processing unit (CPU), a random access memory (RAM), a read only memory (ROM), an auxiliary storage device, and the like. The CPU operates based on a program stored in the ROM or the auxiliary storage device, and controls the operations of the film forming apparatus. The controller 6 may be provided either inside or outside the film forming apparatus. In the case where the controller 6 is provided outside the film forming apparatus 1, the controller 6 is capable of controlling the film forming apparatus through a wired or wireless communication means.

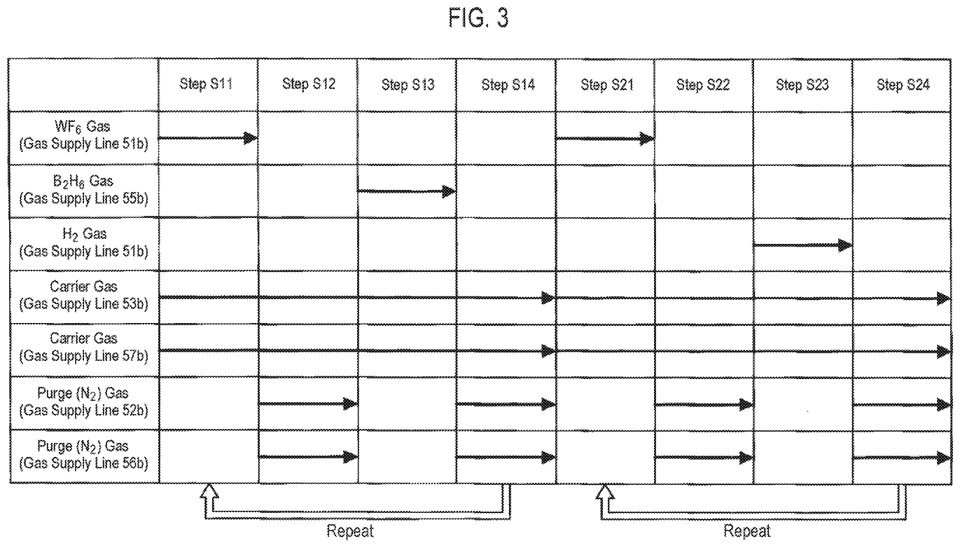

A method of forming a tungsten film using the above-described film forming apparatus will be described. The film forming method according to an embodiment may be applied to a case of forming, by an ALD method, a tungsten film on a wafer W in which a TiN film as a base film is formed on a surface of a silicon film having a recess such as a trench or hole. FIG. 3 is a view illustrating a gas supply sequence in the film forming method of an embodiment.

First, a step S10 of forming an initial tungsten film on a TiN film is executed.

First, in the state in which the valves 51e to 57e are closed, the gate valve 12 is opened, and the wafer W is transferred into the processing container 1 by the transfer mechanism and is placed on the stage 2 that is located at the transfer position. The transfer mechanism is withdrawn from the interior of the processing container 1 and the gate valve 12 is closed. The wafer W is heated to a predetermined temperature (e.g., 200 degrees C. to 250 degrees C.) by the heater 21 of the stage 2, and the stage 2 is raised to the processing position to form the processing space 38. In addition, the pressure control valve of the exhaust mechanism 42 adjusts an internal pressure of the processing container 1 to a predetermined pressure (e.g., 100 Pa to 1,000 Pa).

Subsequently, the valves 53e and 57e are opened. The carrier gases each having a predetermined flow rate (e.g., 1,000 sccm to 10,000 sccm) are supplied from the carrier gas sources 53a and 57a to the gas supply lines 53b and 57b, respectively. In some embodiments, the carrier gas may be selected based on a relationship information representative of the relationship between the type of carrier gas and the film forming rate of the initial tungsten film. The WF₆ gas is supplied from the WF₆ gas source 51a to the gas supply line 51b at a predetermined flow rate (e.g., 50 sccm to 700 sccm). The B₂H₆ gas is supplied from the B₂H₆ gas source 55a to the gas supply line 55b at a predetermined flow rate (e.g., 100 sccm to 5.000 sccm). At this time, since the valves 51e and 55e remain in the closed state, the WF₆ gas and the B₂H₆ gas are stored in the storage tanks 51d and 55d, respectively, so that the internal pressure of each of the storage tanks 51d and 55d is increased.

Subsequently, the valve 51e is opened, and the WF₆ gas stored in the storage tank 51d is supplied into the processing container 1. The WF₆ gas is adsorbed onto the surface of the wafer W (step S11). In addition, in parallel with the supply of the WF₆ gas into the processing container 1, the purge gas (N₂ gas) is supplied from the N₂ gas sources 52a and 56a to the gas supply lines 52b and 56b, respectively. At this time, since the valves 52e and 56e remain in the closed state, the purge gases are stored in the storage tanks 52d and 56d so that the internal pressure of each of the storage tanks 52d and 56d are increased.

After a predetermined period of time (e.g., 0.05 sec to 5 sec) elapses after the valve 51e is opened, the valve 51e is closed and the valves 52e and 56e are opened. Therefore, the supply of the WF₆ gas into the processing container 1 is stopped, and the purge gases stored in respective storage tanks 52d and 56d are supplied into the processing container 1 (step S12). At this time, since the purge gases are supplied from the storage tanks 52d and 56d each having the increased pressure, the purge gases are supplied into the processing container 1 at a relatively large flow rate, for example, a flow rate (e.g., 2,000 sccm to 20,000 sccm) larger than that of the carrier gas. Therefore, the WF₆ gas remaining in the processing container 1 is quickly discharged to the exhaust pipe 41, and the interior of the processing container 1 is replaced from an atmosphere of the WF₆ gas to an atmosphere containing the N₂ gas in a short period of time. Meanwhile, since the valve 51e remains in the closed state, the WF₆ gas supplied from the WF₆ gas source 51a to the gas supply line 51b is stored in the storage tank 51d so that the internal pressure of the storage tank 51d is increased.

After a predetermined period of time (e.g., 0.05 sec to 5 sec) elapses after the valves 52e and 56e are opened, the valves 52e and 56e are closed and the valve 55e is opened. Therefore, the supply of the purge gas into the processing container 1 is stopped, and the B₂H₆ gas stored in the storage tank 55d is supplied into the processing container 1, so that the WF₆ gas adsorbed onto the surface of the wafer W is reduced (step S13). At this time, since the valves 52e and 56e remain in the closed state, the purge gases supplied from the N₂ gas sources 52a and 56a to the gas supply lines 52b and 56b are stored in the storage tanks 52d and 56d, and the internal pressure of each of the storage tanks 52d and 56d is increased.

After a predetermined period of time (e.g., 0.05 sec to 5 sec) elapses after the valve 55e is opened, the valve 55e is closed and the valves 52e and 56e are opened. Therefore, the supply of the B₂H₆ gas into the processing container 1 is stopped, and the purge gas stored in each of the storage tanks 52d and 56d is supplied into the processing container 1 (step S14). At this time, since the purge gases are supplied from the storage tanks 52d and 56d whose internal pressure is increased, the purge gases are supplied into the processing container 1 at a relatively large flow rate, for example, a flow rate (e.g., 2,000 sccm to 20,000 sccm) larger than that of the carrier gas. Therefore, the B₂H₆ gas remaining in the processing container 1 is quickly discharged to the exhaust pipe 41, and the interior of the processing container 1 is replaced from an atmosphere of the B₂H₃ gas to the N₂ gas atmosphere in a short period of time. Meanwhile, by closing the valve 55e, the B₂H₆ gas supplied from the B₂H₆ gas source 55a to the gas supply line 55b is stored in the storage tank 55d, and the interior of the storage tank 55d is increased.

One cycle including steps S11 to S14 described above is repeated to form a thin tungsten unit film on a surface of the TiN film. In addition, an initial tungsten film having a desired film thickness is formed by repeating the cycle of steps S11 to S14 plural times (e.g., 2 cycles to 30 cycles).

Subsequently, a step S20 of forming a main tungsten film on the initial tungsten film is executed.

First, the wafer W is heated to a predetermined temperature (e.g., 300 degrees C. to 600 degrees C.) by the heater 21 of the stage 2. In addition, while maintaining the valves 53e and 57e opened, the carrier gases are continuously supplied from the carrier gas sources 53a and 57a to the gas supply lines 53b and 57b at a predetermined flow rate (e.g., 1,000 sccm to 10,000 sccm), respectively. In addition, the WF₆ gas is supplied from the WF₆ gas source 51a to the gas supply line 51b at a predetermined flow rate (e.g., 50 sccm to 700 sccm). In addition, the H₂ gas is supplied from the H₂ gas source 54a to the gas supply line 54b at a predetermined flow rate (e.g., 500 sccm to 20,000 sccm). At this time, since the valves 51e and 54e remain in the closed state, the WF₆ gas and the HF₆ are stored in the storage tanks 51d and 54d, respectively, so that the internal pressure of each of the storage tanks 51d and 54d is increased.

Subsequently, the valve 51e is opened, and the WF₆ gas stored in the storage tank 51d is supplied into the processing container 1 so as to be adsorbed onto the surface of the wafer W (step S21). In addition, in parallel with the supply of the WF₆ gas into the processing container 1, the purge gases (N₂ gases) are supplied from the N₂ gas sources 52a and 56a to the gas supply lines 52b and 56b, respectively. At this time, since the valves 52e and 56e remain in the closed state, the purge gases are stored in the storage tanks 52d and 56d so that the internal pressure of each of the storage tanks 52d and 56d is increased.

After a predetermined period of time (e.g., 0.05 sec to 5 sec) elapses since the valve 51e is opened, the valve 51e is closed and the valves 52e and 56e are opened. Therefore, the supply of the WF₆ gas into the processing container 1 is stopped, and the purge gases respectively stored in the storage tanks 52d and 56d are supplied into the processing container 1 (step S22). At this time, since the purge gases are supplied from the storage tanks 52d and 56d having the increased pressure, the purge gases are supplied into the processing container 1 at a relatively large flow rate, for example, a flow rate (e.g., 2.000 sccm to 20,000 sccm) larger than that of the carrier gas. Therefore, the WF₆ gas remaining in the processing container 1 is quickly discharged toward the exhaust pipe 41, so that the interior of the processing container 1 is replaced from the atmosphere of the WF₆ gas to an atmosphere containing N₂ gas in a short period of time. Meanwhile, since the valve 51e remains in the closed state, the WF₆ gas supplied from the WF₆ gas source 51a to the gas supply line 51b is stored in the storage tank 51d, so that the internal pressure of the storage tank 51d is increased.

After a predetermined period of time (e.g., 0.05 sec to 5 sec) elapses after the valves 52e and 56e are opened, the valves 52e and 56e are closed and the valve 54e is opened. Therefore, the supply of the purge gas into the processing container 1 is stopped, and the H₂ gas stored in the storage tank 54d is supplied into the processing container 1, so that the WF₆ gas adsorbed onto the surface of the wafer W is reduced (step S23). At this time, since the valves 52e and 56e remain in the closed state, the purge gases supplied from the N₂ gas sources 52a and 56a to the gas supply lines 52b and 56b are stored in the storage tanks 52d and 56d, respectively, so that the internal pressure of each of the storage tanks 52d and 56d is increased.

After a predetermined period of time (e.g., 0.05 sec to 5 sec) elapses after the valve 54e is opened, the valve 54e is closed and the valves 52e and 56e are opened. Therefore, the supply of the H₂ gas into the processing container 1 is stopped, and the purge gas stored in each of the storage tanks 52d and 56d is supplied into the processing container 1 (step S24). At this time, since the purge gases are supplied from the storage tanks 52d and 56d having the increased pressure, the purge gases are supplied into the processing container 1 at a relatively large flow rate, for example, a flow rate (e.g., 2,000 sccm to 20,000 sccm) larger than that of the carrier gas. Therefore, the H₂ gas remaining in the processing container 1 is quickly discharged toward the exhaust pipe 41, and the interior of the processing container 1 is replaced from the atmosphere of the H₂ gas to the N₂ gas atmosphere in a short period of time. Meanwhile, since the valve 54e remains in the closed state, the H₂ gas supplied from the H₂ gas source 54a to the gas supply line 54b is stored in the storage tank 54d so that the internal pressure of the storage tank 54d is increased.

A thin tungsten unit film is formed on the surface of the initial tungsten film by performing one cycle including steps S21 to S24 described above. In addition, the main tungsten film having a desired film thickness is formed by repeating the cycle of steps S21 to 24 plural times (e.g., 2 cycles to 3,000 cycles).

Thereafter, the wafer W is unloaded from the processing container 1 in the reverse procedure to that at the time of loading the wafer W into the processing container 1.

In the above-described embodiment, although the case in which the step S10 of forming the initial tungsten film and the step S20 of forming the main tungsten film are continuously executed in the same processing container 1 has been described, the present disclosure is not limited thereto. For example, the step S10 of forming the initial tungsten film and the step S20 of forming the main tungsten film may be performed in different processing containers. In this case, one processing container in which the step S10 of forming the initial tungsten film is executed and the other processing container in which the step S20 of forming the main tungsten film is executed, may be connected to each other through a vacuum transfer chamber maintained in a depressurized state. The vacuum transfer chamber includes a transfer mechanism provided therein to transfer the wafer W. This makes it possible to prevent a natural oxide film from being formed at an interface between the initial tungsten film and the main tungsten film.

### (Evaluation)

Next, using the film forming apparatus described with reference to FIG. 2, the initial tungsten film was formed on an AlN film as a base film while changing a set temperature of the stage 2. Then, the relationship between the set temperature of the stage 2 and a forming rate of the initial tungsten film was evaluated. Process conditions in the step S10 of forming the initial tungsten film are as follows.

### <Process Conditions>

Set temperature of stage: 150 degrees C. to 300 degrees C.

Carrier gas: mixed gas of H₂ gas and Ar gas (hereinafter, referred to as “H₂ gas/Ar gas”)

Flow rate of carrier gas: H₂ gas/Ar gas (4,000 sccm/2,000 sccm)

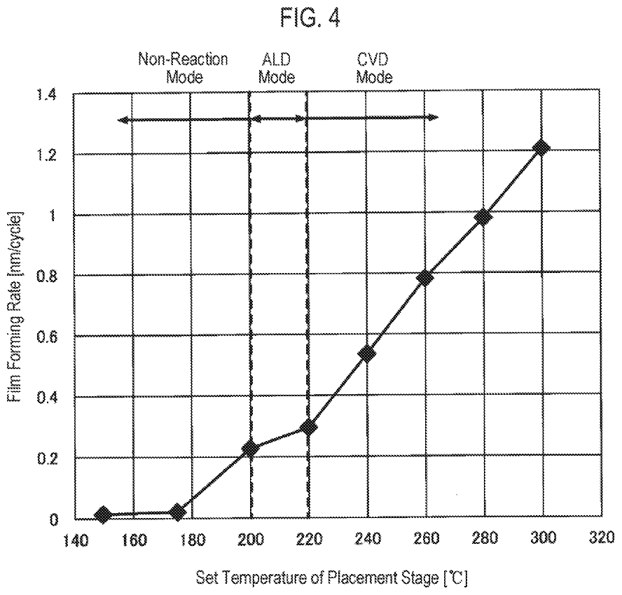

FIG. 4 is a view representing the relationship between the set temperature of the stage 2 and the film forming rate. In FIG. 4, the horizontal axis represents the set temperature of the stage 2 [degrees C.], and the vertical axis represents the film forming rate of the initial tungsten film [nm/cycle].

As shown in FIG. 4, it can be seen that when the set temperature of the stage 2 is 175 degrees C. or lower, the film forming rate of the initial tungsten film is very low. From this, it can be seen that when the set temperature of the stage 2 is 175 degrees C. or lower, a non-reaction mode in which the initial tungsten film is hardly formed on the wafer W is established. Meanwhile, it can be seen that when the set temperature of the stage 2 is 200 degrees C. or higher, the film forming rate of the initial tungsten film is increased as the set temperature of the stage 2 increase. Therefore, from the viewpoint of reliably forming the initial tungsten film on the base film, the temperature at which the initial tungsten film is formed may be 200 degrees or higher.

In addition, as shown in FIG. 4, when the set temperature of the stage 2 falls within a range of 200 degrees to 220 degrees, the film forming rate of the initial tungsten film was about 0.2 nm to 0.3 nm. Thus, it is considered that the film forming mode is an ALD mode. Meanwhile, when the set temperature of the stage 2 is higher than 220 degrees C. the film forming rate of the initial tungsten film rapidly increased as the set temperature of the stage 2 increases. Thus, it is considered that the film forming mode is changed from the ALD mode to a CVD mode. Therefore, from the viewpoint of accurately controlling a film thickness even if the initial tungsten film is formed in the ALD mode and the film thickness of the initial tungsten film is reduced, the temperature at which the initial tungsten film is formed may fall within a range of 200 degrees C. to 220 degrees C.

Subsequently, using the film forming apparatus described with reference to FIG. 2, the initial tungsten film was formed on the AlN film as the base film while changing the type of carrier gas in the step S10 of forming the initial tungsten film. In addition, the relationship between the type of carrier gas and the film forming rate of the initial tungsten film, and the relationship between the type of carrier gas and a concentration of fluorine in the AlN film were evaluated. Process conditions in the step S10 of forming the initial tungsten film are as follows.

### <Process Conditions>

Set temperature of stage: 200 degrees C.

Carrier gas: H₂ gas/Ar gas (4,000 sccm/2,000 sccm), Ar gas (6,000 sccm), N₂ gas (6,000 sccm)

Number of cycles: 5 times, 10 times, 15 times

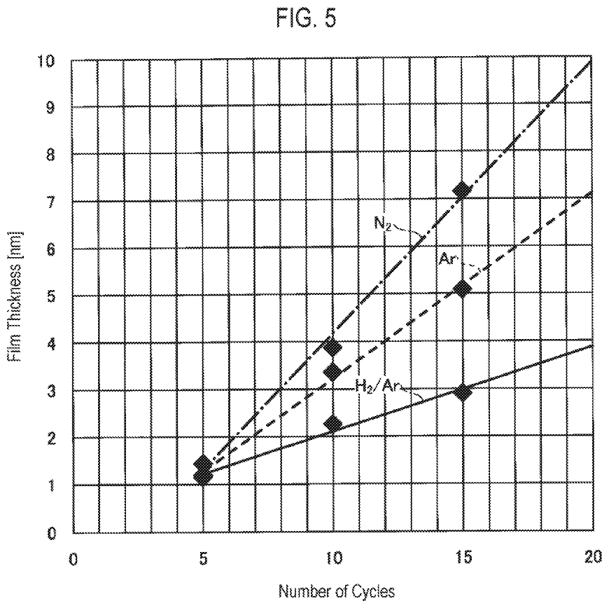

FIG. 5 is a view representing the relationship between the number of cycles and the film thickness of a tungsten film. In FIG. 5, the horizontal axis represents the number of cycles [times] which is the number of repetitions of steps S11 to S14, and the vertical axis represents the film thickness [nm] of the initial tungsten film. In addition, in FIG. 5, a solid line, a broken line, and dashed one-dotted line show approximate curves that represent the relationship between the number of cycles and the film thickness of the initial tungsten film when the H₂ gas/Ar gas, the Ar gas, and the N₂ gas are used as the carrier gases, respectively.

As shown in FIG. 5, it can be seen that it is possible to control the film forming rate of the initial tungsten film by changing the type of carrier gas in the step S10 of forming the initial tungsten film. For example, when the H₂ gas/Ar gas is used as the carrier gas, the film forming rate of the initial tungsten film is expressed as a slope of the approximate curve represented by the solid line, and was calculated as 0.18 nm/cycle. When the Ar gas is used as the carrier gas, the film forming rate of the initial tungsten film is expressed as a slope of the approximate curve represented by the broken line, and was calculated as 0.39 nm/cycle. In addition, when the N₂ gas is used as the carrier gas, the film forming rate of the initial tungsten film is expressed as a slope of the approximate curve represented by the dashed one-dotted line, and was calculated as 0.57 nm/cycle.

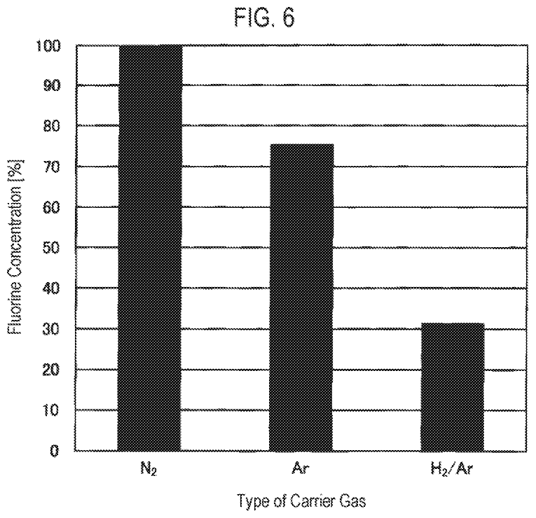

FIG. 6 is a view representing the relationship between the type of carrier gas and a concentration of fluorine in an AlN film. In FIG. 6, assuming that the fluorine concentration in the AlN film is 100% when the initial tungsten film was formed using the N₂ gas as a carrier gas, the fluorine concentration [%] in the AlN film when the Ar gas and the H₂ gas/Ar gas were used as a carrier gas, is shown.

As shown in FIG. 6, it can be seen that it is possible to control the fluorine concentration in the AlN film by changing the type of carrier gas in the step S10 of forming the initial tungsten film. For example, it can be seen that, when the H₂ gas/Ar gas was used as a carrier gas, the fluorine concentration was reduced to about 1/3 compared to the case where the N₂ gas was used. In addition, it can be seen that, when the Ar gas was used as the carrier gas, the fluorine concentration was reduced to about 3/4 compared to the case where N₂ gas was used.

From the results of FIGS. 5 and 6 described above, it can be seen that it is possible to control the film forming rate of the initial tungsten film and to control the fluorine concentration in the AlN film by changing the type of carrier gas. Therefore, by obtaining in advance the relationship information representative of the relationship between the type of carrier gas and the film forming rate of the initial tungsten film as shown in FIG. 5, and supplying the carrier gas selected based on the relationship information in the step S10 of forming the initial tungsten film, it is possible to adjust the fluorine concentration in the base film. As an example, when it is desired to form an initial tungsten film so as to reduce the fluorine concentration in the base film, the H₂ gas/Ar gas may be selected as a carrier gas based on the above-mentioned relationship information.

According to the present disclosure, it is possible to control a film thickness of an initial tungsten film with high accuracy.

It should be noted that the embodiments disclosed herein are exemplary in all respects and are not restrictive. The above-described embodiments may be omitted, replaced or modified in various forms without departing from the scope and spirit of the appended claims.

What is claimed is:

1. A film forming method comprising:
forming an initial tungsten film on a base film formed on a substrate by alternately supplying a B₂H₆ gas and a WF₆ gas while supplying a carrier gas into a processing container in a state in which the substrate is heated to a first temperature within the processing container maintained in a depressurized state; and
forming a main tungsten film on the initial tungsten film by alternately supplying a tungsten-containing gas and a reducing gas for reducing the tungsten-containing gas into the processing container in a state in which the substrate is heated to a second temperature higher than the first temperature within the processing container maintained in the depressurized state.

2. The film forming method of claim 1, wherein the first temperature falls within a range of 200 degrees C. to 220 degrees C.

3. The film forming method of claim 1, wherein the forming the initial tungsten film comprises supplying the carrier gas selected based on a relationship information representative of relationship between the type of the carrier gas and a film forming rate of the initial tungsten film.

4. The film forming method of claim 1, wherein the carrier gas comprises at least one selected from the group of an H₂ gas, an Ar gas, and an N₂ gas.

5. The film forming method of claim 1, wherein the carrier gas comprises an H₂ gas as a main component.

6. The film forming method of claim 1, wherein the base film is a Ti-containing film or an Al-containing film.

7. The film forming method of claim 1, wherein the forming the initial tungsten film and the forming the main tungsten film are performed in the same processing container.

8. The film forming method of claim 1, wherein the forming the initial tungsten film and the forming the main tungsten film are performed in different processing containers.

9. A film forming apparatus comprising:
a processing container in which a substrate is accommodated;
a heater configured to heat the substrate;
a gas supply mechanism configured to supply at least a B₂H₆ gas, a WF₆ gas, a tungsten-containing gas, and a reducing gas into the processing container;
an exhaust part configured to exhaust an interior of the processing container; and
a controller,
wherein the controller is configured to control operations of the heater, the gas supply mechanism, and the exhaust part so as to execute steps of:
forming an initial tungsten film on a base film formed on a substrate by alternately supplying the B₂H₆ gas and the WF₆ gas while supplying a carrier gas into the processing container in a state in which the substrate is heated to a first temperature within the processing container; and
forming a main tungsten film on the initial tungsten film by alternately supplying the tungsten-containing gas and the reducing gas for reducing the tungsten-containing gas into the processing container in a state in which the substrate is heated to a second temperature higher than the first temperature within the processing container.
